(19) United States
(12) Patent Application Publication
(10) Pub. No.: US 2026/0173978 A1
(43) Pub. Date: Jun. 18, 2026

(54) SEMICONDUCTOR DEVICE

(71) Applicant: FUJI ELECTRIC CO., LTD., Kawasaki-shi (JP)

(72) Inventors: Shogo MIZUNO, Matsumoto-city (JP); Tsubasa NAKAMURA, Matsumoto-city (JP); Yuto UEMATSU, Matsumoto-city (JP); Yoshinori OTOMO, Matsumoto-city (JP)

(73) Assignee: FUJI ELECTRIC CO., LTD., Kawasaki-shi (JP)

(21) Appl. No.: 19/373,533

(22) Filed: Oct. 29, 2025

(30) Foreign Application Priority Data
Dec. 18, 2024 (JP) 2024-221557

(51) Int. Cl. H01L 23/498; H01L 21/48; H01L 23/00; H01L 23/057; H01L 23/46; H01L 25/065

(52) U.S. Cl. CPC H10W 90/701; H10W 70/093; H10W 76/157; H10W 90/00; H10W 40/40; H10W 72/886; H10W 90/734; H10W 90/764

(57) ABSTRACT

A semiconductor device, including: a conductive plate; a case having a frame shape in a plan view of the semiconductor device, to thereby form an inner accommodating region in which the conductive plate is housed; and a terminal, including: a wiring portion that is partially fixed to the case and extends into the inner accommodating region, and a bonding portion including a bonding surface bonded to the conductive plate, and a main surface opposite to the bonding surface, and having indentations formed thereon. The wiring portion includes an extended portion extending from the case, the extended portion including a thinned portion that is thinner than all other portions of the terminal excluding the extended portion.

### CROSS-REFERENCE TO RELATED APPLICATION

This application is based upon and claims the benefit of priority of the prior Japanese Patent Application No. 2024-221557, filed on Dec. 18, 2024, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a semiconductor chip, an insulated circuit board on which the semiconductor chip is provided, and a case that accommodates the semiconductor chip and the insulated circuit board and has integrally molded external connection terminals. Inside the case, the external connection terminals are electrically connected to conductive plates included in the insulated circuit board (see, for example, patent documents (1) to (5) below ).

(1) Japanese Laid-open Patent Publication No. H04-364768

(2) Japanese Laid-open Patent Publication No. 2024-111999

(3) Japanese Laid-open Patent Publication No. 2023-031941

(4) Japanese Laid-open Patent Publication No. 2017-139304

(5) Japanese Laid-open Patent Publication No. 2015-046416

### SUMMARY OF THE INVENTION

According to an aspect of the present disclosure, there is provided a semiconductor device including: a conductive plate; a case having a frame shape in a plan view of the semiconductor device, to thereby form an inner accommodating region in which the conductive plate is housed; and a terminal, including: a wiring portion that is partially fixed to the case and extends into the inner accommodating region, and a bonding portion, including: a bonding surface bonded to the conductive plate, and a main surface opposite to the bonding surface, and having indentations formed thereon, wherein the wiring portion includes an extended portion extending from the case, the extended portion including a thinned portion that is thinner than all other portions of the terminal excluding the extended portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a cross-sectional view of the semiconductor device according to the first embodiment;

FIG. 3 is a plan view of a semiconductor unit included in the semiconductor device of the first embodiment;

FIG. 4 is a side view of the semiconductor device according to the first embodiment;

FIG. 5 is a cross-sectional view of a bonding portion of a connection terminal of the semiconductor device according to the first embodiment;

FIG. 6 is a plan view of the connection terminal of the semiconductor device according to the first embodiment;

FIG. 7 illustrates bonding of the connection terminal of the semiconductor device according to the first embodiment;

FIG. 8 is a first diagram for illustrating bonding of a connection terminal of a semiconductor device in a first reference example;

FIG. 9 is a second diagram for illustrating the bonding of the connection terminal of the semiconductor device in the first reference example;

FIG. 10 illustrates the bonding of the connection terminal of the semiconductor device in the first reference example;

FIG. 11 is a plan view of a semiconductor device of a second reference example;

FIG. 12 is a cross-sectional view of the bonding portion of the connection terminal in the semiconductor device according to the first embodiment (a modification 1-1);

FIG. 13 is a cross-sectional view of the bonding portion of the connection terminal in the semiconductor device according to the first embodiment (a modification 1-2);

FIG. 14 is a cross-sectional view of a bonding portion of a connection terminal in a semiconductor device according to a second embodiment ;

FIG. 15 illustrates bonding of the connection terminal of the semiconductor device according to the second embodiment;

FIG. 16 is a graph illustrating an area of a bonded region in relation to notch depth of the connection terminal in the second embodiment;

FIG. 17 is a graph illustrating the area of the bonded region of the connection terminal in the semiconductor device according to the second embodiment, in relation to the number of thermal cycles;

FIG. 18 is a cross-sectional view of the bonding portion of the connection terminal in the semiconductor device according to the second embodiment (a modification 2-1);

FIG. 19 is a cross-sectional view of the bonding portion of the connection terminal in the semiconductor device according to the second embodiment (a modification 2-2);

FIG. 20 is a cross-sectional view of the bonding portion of the connection terminal in the semiconductor device according to the second embodiment (a modification 2-3); and

FIG. 21 is a plan view illustrating a connection terminal of a semiconductor device according to a third embodiment.

### DETAILED DESCRIPTION OF THE INVENTION

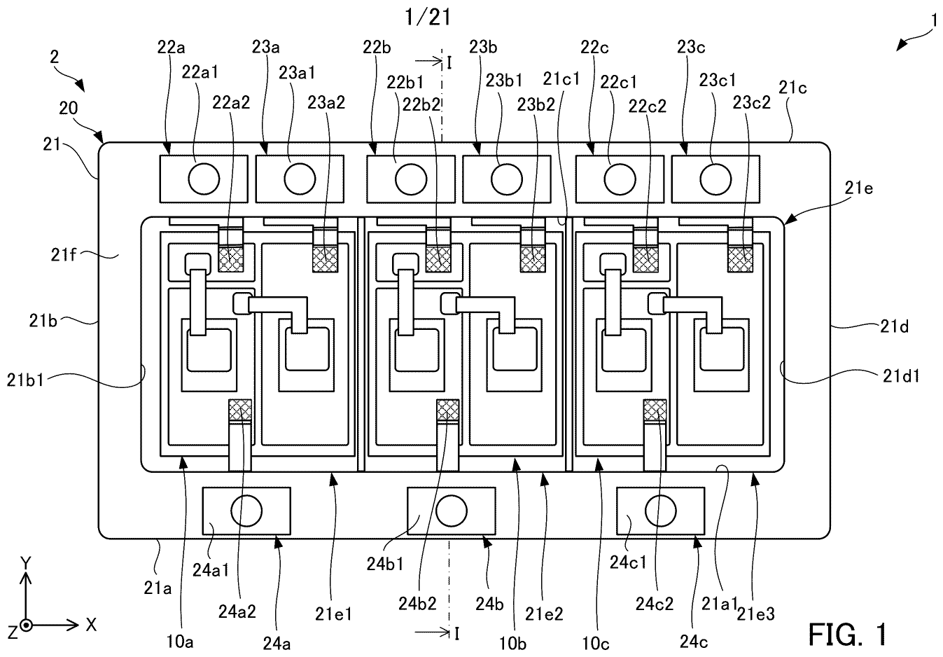

Hereinafter, embodiments will be described with reference to the drawings. In the following description, the terms “front surface” and “upper surface” refer to an X-Y plane facing upward (in the +Z direction) in a semiconductor device 1 of FIGS. 1, 2, and 4. Similarly, the term “upper” refers to the direction upward (the +Z direction) in the semiconductor device 1 of FIGS. 1, 2, and 4. The terms “back surface” and “lower surface” refers to the X-Y plane facing downward (in the-Z direction) in the semiconductor device 1 of FIGS. 1, 2, and 4. Similarly, the term “lower” refers to the direction downward (the-Z direction) in the semiconductor device 1 of FIGS. 1, 2, and 4. The same directional conventions apply to other drawings as needed. The terms “high position” and “upper position” refer to positions located upward (in the +Z direction) in the semiconductor device 1 of FIGS. 1, 2, and 4. Similarly, the terms “low position” and “lower position” refer to positions located downward (in the −Z direction) in the semiconductor device 1 of FIGS. 1, 2, and 4. The terms “front surface”, “upper surface”, “upper”, “rear surface”, “lower surface”, “lower”, and “side surface” are merely used for convenience to indicate relative positional relationships and do not limit the technical scope of the present disclosure. For example, the terms “upper” and “lower” do not necessarily refer to the vertical direction with respect to the ground. That is, the directions “upper” and “lower” are not limited to the direction of gravity. In addition, in the following description, the term “main component” indicates a case where the content is 80 vol% or more. The term “substantially the same” indicates a range within ±10%. The terms “vertical”, “orthogonal”, and “parallel” indicate a range within ±10°.

### (a) First Embodiment

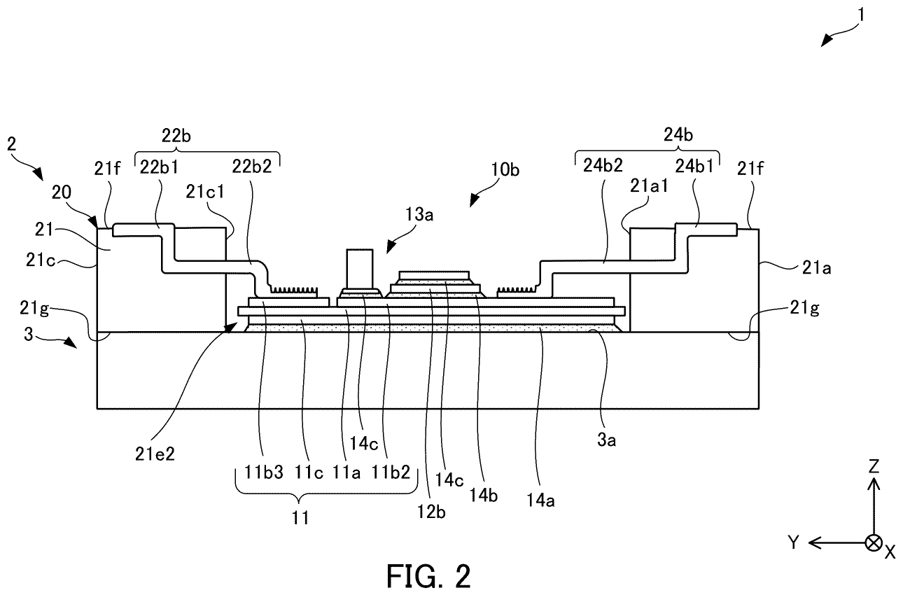

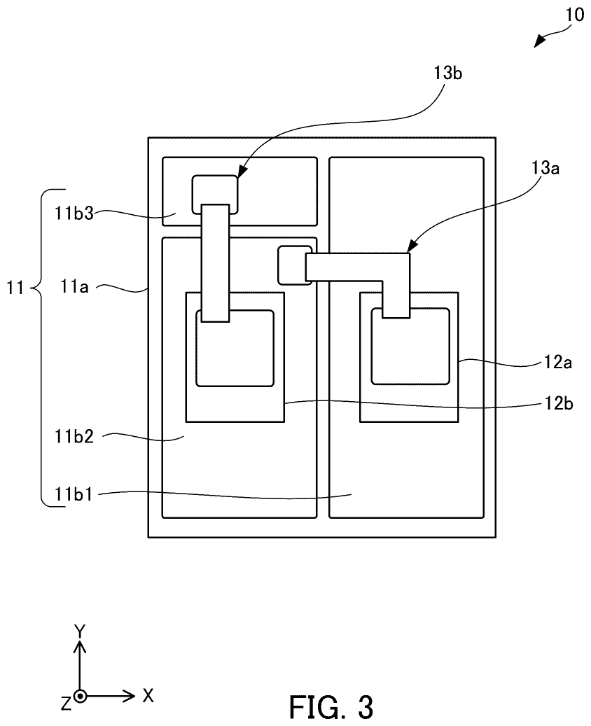

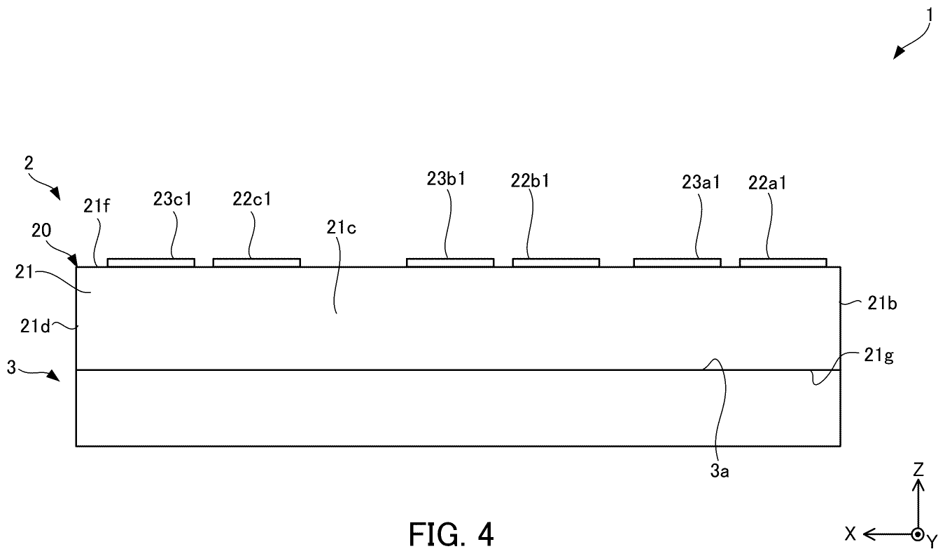

The semiconductor device 1 according to a first embodiment will be described with reference to FIGS. 1 to 4. FIG. 1 is a plan view of the semiconductor device according to the first embodiment. FIG. 2 is a cross-sectional view of the semiconductor device according to the first embodiment. FIG. 3 is a plan view of the semiconductor unit included in the semiconductor device of the first embodiment. FIG. 4 is a side view of the semiconductor device according to the first embodiment. The cross-sectional view of FIG. 2 is taken along a dashed-dotted line I-I in FIG. 1. The side view of FIG. 4 is a view of the semiconductor device 1 depicted in FIG. 1, as viewed in the +Y direction (the Z-X plane). In FIGS. 1 and 2, a sealing member is not illustrated. The sealing member may be filled in each of unit accommodating regions 21e1, 21e2, and 21e3 of a case 20.

The semiconductor device 1 includes a semiconductor module 2 and a cooling module 3. The semiconductor module 2 includes semiconductor units 10a, 10b, and 10c and the case 20 that accommodates the semiconductor units 10a, 10b, and 10c. The semiconductor units 10a, 10b, and 10c housed in the case 20 are sealed with a sealing member (not illustrated).

The semiconductor units 10a, 10b, and 10c have the same configuration. When no distinction is made among the semiconductor units 10a, 10b, and 10c, the semiconductor units 10a, 10b, and 10c collectively referred to as semiconductor unit 10. Details of the semiconductor unit 10 will be described later.

The case 20 includes a frame portion 21, first connection terminals 22a, 22b, and 22c, second connection terminals 23a, 23b, and 23c, a W-phase output terminal 24a, a V-phase output terminal 24b, a U-phase output terminal 24c, and control terminals (not illustrated).

The frame portion 21 has a substantially rectangular shape in plan view, and includes outer walls 21a, 21b, 21c, and 21d surrounding four sides in order and inner walls 21a1, 21b1, 21c1, and 21d1 facing the outer walls 21a, 21b, 21c, and 21d, respectively. Further, the frame portion 21 includes an upper surface 21f and a lower surface 21g connected to the outer walls 21a, 21b, 21c, and 21d and the inner walls 21a1, 21b1, 21c1, and 21d1. The outer walls 21a and 21c and the inner walls 21a1 and 21c1 extend in the longitudinal direction corresponding to the long sides of the frame portion 21, while the outer walls 21b and 21d and the inner walls 21b1 and 21d1 extend in the lateral direction corresponding to the short sides the frame portion 21. In addition, the corner portions that are connection points of the outer walls 21a, 21b, 21c, and 21d, and the connection points of the inner walls 21a1, 21b1, 21c1, and 21d1, do not have to be right angles and may be R-chamfered, as illustrated in FIG. 1. Through-holes (not illustrated) that penetrate the frame portion 21 in the +Z direction may be formed respectively at the corner portions of the upper surface 21f and the lower surface 21g of the frame portion 21.

The frame portion 21 includes, on the inside, an opening region 21e that is surrounded on all four sides in sequence by the inner walls 21a1, 21b1, 21c1, and 21d1. That is, the opening region 21e has a rectangular shape in plan view and is defined by the inner walls 21a1, 21b1, 21c1, and 21d1. The opening region 21e is open from the upper surface 21f to the lower surface 21g of the frame portion 21.

Furthermore, the frame portion 21 includes, within the opening region 21e, the unit accommodating regions 21e1, 21e2, and 21e3, which are accommodating regions for the semiconductor units 10a, 10b, and 10c, respectively. The unit accommodating regions 21e1, 21e2, and 21e3 are provided sequentially along the outer walls 21a and 21c and the inner walls 21a1 and 21c1 within the opening region 21e, which is divided into three parts in plan view. A stepped portion may be formed in the inner wall 21a1 on the side of the outer wall 21a in each of the unit accommodating regions 21e1, 21e2, and 21e3. The semiconductor units 10a, 10b, and 10c are respectively accommodated in the unit accommodating regions 21e1, 21e2, and 21e3.

The semiconductor units 10a, 10b, and 10c are respectively bonded to a cooling surface 3a of the cooling module 3 via bonding members 14a. When the frame portion 21 is attached to the cooling surface 3a of the cooling module 3, the semiconductor units 10a, 10b, and 10c are respectively accommodated in the unit accommodating regions 21e1, 21e2, and 21e3 of the frame portion 21. The frame portion 21 may be bonded to the cooling surface 3a of the cooling module 3 with an adhesive.

The frame portion 21 is provided, in plan view, with the first connection terminals 22a, 22b, and 22c, and the second connection terminals 23a, 23b, and 23c, on the side of the outer wall 21c. The first connection terminals 22a, 22b, and 22c respectively include connecting portions 22a1, 22b1, and 22c1 at their first ends, and bonding portions 22a2, 22b2, and 22c2 at their second ends. Similarly, the second connection terminals 23a, 23b, and 23c respectively include connecting portions 23a1, 23b1, and 23c1 at their first ends, and bonding portions 23a2, 23b2, and 23c2 at their second ends.

The connecting portions 22a1, 22b1, and 22c1, and the connecting portions 23a1, 23b1, and 23c1, which are the first ends of the first connection terminals 22a, 22b, and 22c and the second connection terminals 23a, 23b, and 23c, are arranged on the upper surface 21f on the side of the outer wall 21c. These connecting portions (reference numerals omitted) may have openings formed therein. Nuts may be accommodated in the upper surface 21f of the frame portion 21, where the connecting portions are arranged, so as to face the openings of the connecting portions.

The bonding portions 22a2, 22b2, and 22c2, and the bonding portions 23a2, 23b2, and 23c2, which are the second ends of the first connection terminals 22a, 22b, and 22c and the second connection terminals 23a, 23b, and 23c, extend into the unit accommodating regions 21e1, 21e2, and 21e3 and are electrically connected to the semiconductor units 10a, 10b, and 10c.

Some of the intermediate portions between the connecting portions and the bonding portions of the first connection terminals 22a, 22b, and 22c and the second connection terminals 23a, 23b, and 23c are included within the frame portion 21, while the remaining portions are exposed in the unit accommodating regions 21e1, 21e2, and 21e3 of the frame portion 21. The first connection terminals 22a, 22b, and 22c and the second connection terminals 23a, 23b, and 23c may have the same configuration. Details of the first connection terminals 22a, 22b, and 22c and the second connection terminals 23a, 23b, and 23c will be described later.

The frame portion 21 is provided, in plan view, with the W-phase output terminal 24a, the V-phase output terminal 24b, and the U-phase output terminal 24c, on the side of the outer wall 21a. The W-phase output terminal 24a, the V-phase output terminal 24b, and the U-phase output terminal 24c respectively include connecting portions 24a1, 24b1, and 24c1 at their first ends, and bonding portions 24a2, 24b2, and 24c2 at their second ends.

The connecting portions 24a1, 24b1, and 24c1 at the first ends are arranged on the upper surface 21f on the side of the outer wall 21a. These connecting portions may have openings formed therein. Nuts may be accommodated in the upper surface 21f of the frame portion 21, where the connecting portions are arranged, so as to face the openings of the connecting portions.

The bonding portions 24a2, 24b2, and 24c2 at the second ends are exposed in the unit accommodating regions 21e1, 21e2, and 21e3 and are electrically connected to the semiconductor units 10a, 10b, and 10c. Some of the intermediate portions between the connecting portions and the bonding portions of the W-phase output terminal 24a, the V-phase output terminal 24b, and the U-phase output terminal 24c are included within the frame portion 21, while the remaining portions are exposed in the unit accommodating regions 21e1, 21e2, and 21e3 of the frame portion 21. The W-phase output terminal 24a, the V-phase output terminal 24b, and the U-phase output terminal 24c may have the same configuration.

Accordingly, in plan view, the frame portion 21 includes the first connection terminal 22a and the second connection terminal 23a on the outer wall 21c side and the W-phase output terminal 24a on the outer wall 21a side, with the unit accommodating region 21e1 interposed therebetween. Similarly, in plan view, the frame portion 21 includes the first connection terminal 22b and the second connection terminal 23b on the outer wall 21c side and the V-phase output terminal 24b on the outer wall 21a side, with the unit accommodating region 21e2 interposed therebetween. Likewise, in plan view, the frame portion 21 includes the first connection terminal 22c and the second connection terminal 23c on the outer wall 21c side and the U-phase output terminal 24c on the outer wall 21a side, with the unit accommodating region 21e3 interposed therebetween.

The frame portion 21 may further be provided, in plan view, with control terminals (not illustrated) along the outer wall 21a, on the part of the upper surface 21f facing the outer wall 21a, for each of the unit accommodating regions 21e1, 21e2, and 21e3. The control terminals are electrically connected to control electrodes of semiconductor chips included in the semiconductor units 10a, 10b, and 10c, respectively. Each control terminal may be connected to the corresponding control electrode of the semiconductor chip via a wire. The wire has, as its main component, a material with excellent electrical conductivity. Such a material may be, for example, gold, copper, aluminum, or an alloy containing at least one of these. Preferably, the wire may be made of an aluminum alloy containing a trace amount of silicon.

The first connection terminals 22a, 22b, and 22c, the second connection terminals 23a, 23b, and 23c, the W-phase output terminal 24a, the V-phase output terminal 24b, and the U-phase output terminal 24c are each made of a metal having excellent conductivity. Such a metal is, for example, copper, aluminum, or an alloy containing at least one 41 these as a main component. The surfaces of the first connection terminals 22a, 22b, and 22c, the second connection terminals 23a, 23b, and 23c, the W-phase output terminal 24a, the V-phase output terminal 24b, and the U-phase output terminal 24c may be subjected to plating. The plating material used in this case may be, for example, nickel, a nickel-phosphorus alloy, or a nickel-boron alloy.

The frame portion 21, which includes the first connection terminals 22a, 22b, and 22c, the second connection terminals 23a, 23b, and 23c, the W-phase output terminal 24a, the V-phase output terminal 24b, and the U-phase output terminal 24c, is integrally molded by injection molding using a thermoplastic resin. At this time, a lower shielding plate, described later, may also be integrally molded. The thermoplastic resin may be, for example, a polyphenylene sulfide resin, a polybutylene terephthalate resin, a £ polybutylene succinate resin, a polyamide resin, or an acrylonitrile butadiene styrene resin.

A sealing member (not illustrated) that seals the unit accommodating regions 21e1, 21e2, and 21e3 of the frame portion 21 may be made of a silicone gel or a thermosetting resin. The thermosetting resin may be, for example, an epoxy resin, a phenol resin, a maleimide resin, or a polyester resin. The sealing member seals the entirety of the semiconductor units 10a, 10b, and 10 c housed in the unit accommodating regions 21e1, 21e2, and 21e3, while the entire unit accommodating regions 21e1, 21e2, and 21e3 may remain partially unsealed. Preferably, the portions of the first connection terminals 22a, 22b, and 22c, the second connection terminals 23a, 23b, and 23c, the W-phase, V-phase, and U-phase output terminals 24a, 24b, and 24c, and the control terminals that are exposed in the unit accommodating regions 21e1, 21e2, and 21e3 are sealed.

The semiconductor unit 10 may be a device that constitutes an inverter circuit for a single phase. The semiconductor unit 10 includes an insulated circuit board 11, two semiconductor chips 12a and 12b, and lead frames 13a and 13b. The semiconductor chips 12a and 12b are joined to the insulated circuit board 11 by bonding members 14b. The lead frames 13a and 13b are joined to the main electrodes on the upper surfaces of the semiconductor chips 12a and 12b and the upper surface of the insulated circuit board 11 by bonding members 14c. The lead frames 13a and 13b may alternatively be joined to the insulated circuit board 11 by ultrasonic bonding instead of using the bonding members 14c.

The insulated circuit board 11 includes an insulating plate 11a, conductive circuit patterns 11b1, 11b2, and 11b3, and a metal plate 11c. The insulating plate 11a is rectangular in plan view. The corners of the insulating plate 11a may be R-chamfered or C-chamfered.

The insulating plate 11a is made of a material having insulating properties and excellent thermal conductivity. The insulating plate 11a may be made of ceramics. The ceramics may be, for example, aluminum oxide, aluminum nitride, or silicon nitride.

Alternatively, the insulating plate 11a may be made of a resin. The resin may be a material having high insulation and low thermal resistance. Such a resin may be, for example, a thermosetting resin. The thermosetting resin may further contain a filler. Examples of such thermosetting resin include at least one selected from epoxy resins, cyanate resins, polyimide resins, benzoxazine resins, unsaturated polyester resins, phenol resins, melamine resins, silicone resins, maleimide resins, acrylic resins, and polyamide resins. The filler may be made of at least one of oxides and nitrides. Examples of oxides include silicon oxide and aluminum oxide. Examples of nitrides include silicon nitride, aluminum nitride, and boron nitride. The filler may also be hexagonal boron nitride.

The conductive circuit patterns 11b1, 11b2, and 11b3 are examples of conductive plates, and are formed on the front surface of the insulating plate 11a. The conductive circuit patterns 11b1, 11b2, and 11b3 are made of a metal having excellent conductivity. Such a metal may be, for example, copper, aluminum, or an alloy containing at least of these as a main component. To improve corrosion resistance, the surfaces of the conductive circuit patterns 11b1, 11b2, and 11b3 may be subjected to plating. The plating material used in this case may be, for example, nickel, a nickel-phosphorus alloy, or a nickel-boron alloy.

The conductive circuit pattern 11b1 is formed in the half region on the +X-direction side of the front surface of the insulating plate 11a and spans the entire area from the-Y-direction edge to the +Y-direction edge. The bonding portions 23a2, 23b2, and 23c2 of the second connection terminals 23a, 23b, and 23c are joined to the conductive circuit pattern 11b1. These may be joined by ultrasonic bonding.

The conductive circuit pattern 11b2 is formed in the half region on the-X-direction side of the front surface of the insulating plate 11a. Furthermore, the conductive circuit pattern 11b2 extends from the-Y-direction edge to a location short of the +Y-direction edge. Each of the bonding portions 24a2, 24b2, and 24c2 of the W-phase output terminal 24a, the V-phase output terminal 24b, and the U-phase output terminal 24c is respectively joined to the conductive circuit pattern 11b2. These may also be joined by ultrasonic bonding.

The conductive circuit pattern 11b3 is formed in the region surrounded by the conductive circuit patterns 11b1 and 11b2 on the upper surface of the insulating plate 11a. The bonding portions 22a2, 22b2, and 22c2 of the first connection terminals 22 a, 22 b, and 22c are joined to the conductive circuit pattern 11b3. These may also be joined by ultrasonic bonding.

The metal plate 11c is formed on the lower surface of the insulating plate 11a and has a rectangular shape. The area of the metal plate 11c in plan view is smaller than that of the insulating plate 11a, but larger than that of the region where the conductive circuit patterns 11b1, 11b2, and 11b3 are formed. The corners of the metal plate 11c may be R-chamfered or C-chamfered. The metal plate 11c is formed over the entire surface of the insulating plate 11a excluding its edges. The metal may be, for example, copper, aluminum, or an alloy containing at least one of these. The surface of the metal plate 11c may be plated to improve corrosion resistance. The plating material used may be, for example, nickel, a nickel-phosphorus alloy, or a nickel-boron alloy.

When the insulating plate 11a is made of ceramics, the insulated circuit board 11 may be, for example, a direct copper bonding (DCB) substrate or an active metal brazed (AMB) substrate. The insulated circuit board 11 may be mounted on the cooling surface 3a of the cooling module 3 via the bonding member 14a. Heat generated by the semiconductor chips 12a and 12b is conducted to the cooling module 3 via the conductive circuit patterns 11b1 and 11b2, the insulating plate 11a, and the metal plate 11c, and then dissipated.

The bonding member 14a may be a brazing material or a thermal interface material. The brazing material contains, for example, at least one of an aluminum alloy, a titanium alloy, a magnesium alloy, a zirconium alloy, and a silicon alloy as a main component. The thermal interface material may include various materials such as thermal grease, elastomer sheets, room temperature vulcanization (RTV) rubber, gels, and phase-change materials. By attaching the semiconductor unit 10 to the cooling module 3 via such a brazing material or thermal interface material, the heat dissipation performance of the semiconductor unit 10 is improved.

The bonding members 14b and 14c may be solder. As the solder, lead-free solder is used. The lead-free solder contains, for example, an alloy containing at least two of tin, silver, copper, zinc, antimony, indium, and bismuth as a main component. The solder may further contain an additive. The additive is, for example, nickel, germanium, cobalt, or silicon. Including such an additive improves wettability, glossiness, and bonding strength, thereby enhancing reliability. The bonding member 14a may particularly be a sintered body. When bonding with a sintered body, the sintering material may be, for example, powder of silver, iron, copper, aluminum, titanium, nickel, tungsten, or molybdenum.

The semiconductor chips 12a and 12b include power device elements containing silicon as a main component. The power device elements are reverse-conducting insulated gate bipolar transistors (RC-IGBTs). The RC-IGBTS combine the functions of a switching element, namely the IGBT, and a diode element, namely the free wheeling diode (FWD). On the upper surfaces of the semiconductor chips 12a and 12b, a control electrode (such as a gate electrode) and an output electrode (emitter electrode), which is a main electrode, are provided. On the lower surfaces of the semiconductor chips 12a and 12b, an input electrode (collector electrode), which is a main electrode, is provided. The control electrode may be provided along one side of the upper surface of each of the semiconductor chips 12a and 12b (or at the central portion of one side). The output electrode may be provided at the central portion of the upper surface of each of the semiconductor chips 12a and 12b. The lead frames 13a and 13b are electrically and mechanically bonded to the output electrodes of the semiconductor chips 12a and 12b.

The semiconductor chips 12a and 12b may include switching elements consisting of power metal-oxide-semiconductor field-effect transistors (power MOSFETs) having silicon carbide as a main component. The semiconductor chips 12a and 12b each include, on their front surface, a control electrode (such as a gate electrode) and an output electrode, which is a main electrode (such as a source electrode). The semiconductor chips 12a and 12b include, on their rear surface, an input electrode, which is a main electrode (such as a drain electrode).

Alternatively, each of the semiconductor chips 12a and 12b may employ a set of a switching element and a diode element, each having silicon or silicon carbide as a main component. The switching element may be, for example, an IGBT or a power MOSFET. The semiconductor chips 12a and 12b each include, for example, an input electrode (such as a drain electrode or a collector electrode), which is a main electrode, on the rear surface, and a control electrode (such as a gate electrode) and an output electrode (such as a source electrode or an emitter electrode), which is a main electrode, on the front surface. The diode element may be, for example, an FWD such as a Schottky barrier diode (SBD) or a P-intrinsic-N (PiN) diode. The semiconductor chips 12a and 12b each include, on the rear surface, an output electrode (such as a cathode electrode), which is a main electrode, and on the front surface, an input electrode (such as an anode electrode), which is also a main electrode.

The lead frames 13a and 13b electrically connect and wire the semiconductor chips 12a and 12b to the conductive circuit patterns 11b2 and 11b3, respectively. The lead frame 13a directly connects a main electrode of the semiconductor chip 12a to the conductive circuit pattern 11b2 via the above-mentioned bonding member 14c. The lead frame 13b directly connects a main electrode of the semiconductor chip 12b to the conductive circuit pattern 11b3 via the above-mentioned bonding member 14c. The lead frames 13a and 13b may be bonded to the conductive circuit patterns 11b2 and 11b3 by ultrasonic bonding.

The lead frames 13a and 13b are made of a metal having excellent conductivity. The metal may be, for example, copper, aluminum, or an alloy containing at least one of these as a main component. To improve corrosion resistance, the surfaces of the lead frames 13a and 13b may be subjected to plating. The plating material used may be, for example, nickel, a nickel-phosphorus alloy, or a nickel-boron alloy.

The cooling module 3 includes, on its front side, the cooling surface 3a on which the semiconductor module 2 is placed. Specifically, as described above, the frame portion 21 is mounted on the cooling surface of the cooling module 3, on which the semiconductor units 10a, 10b, and 10c are disposed. The cooling surface 3a is wider than the rear surface of the semiconductor module 2 and is flat. The cooling module 3 may be, for example, a heat-dissipating base equipped with heat-dissipating fins, or a cooling device through which coolant circulates internally.

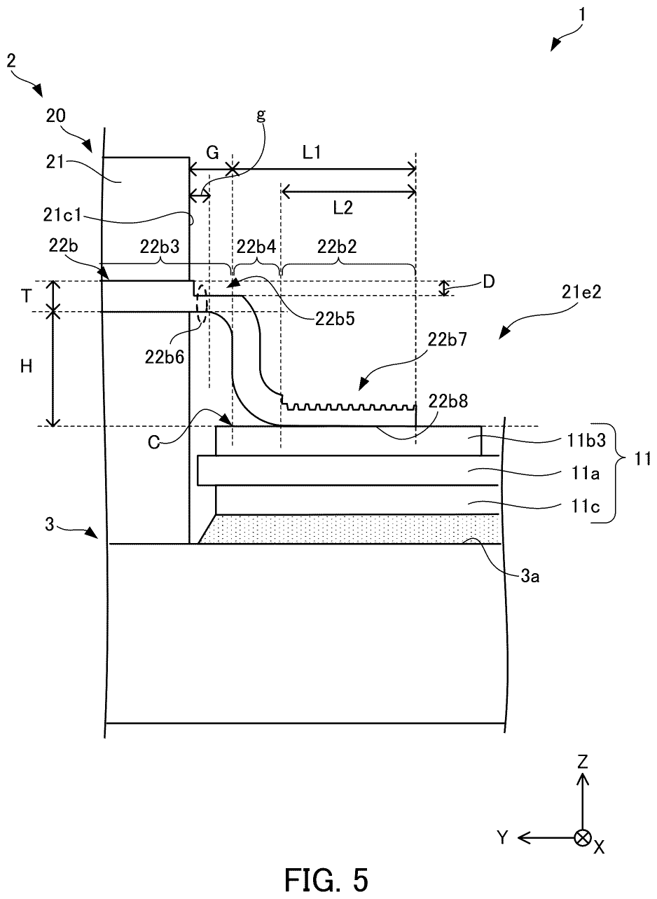

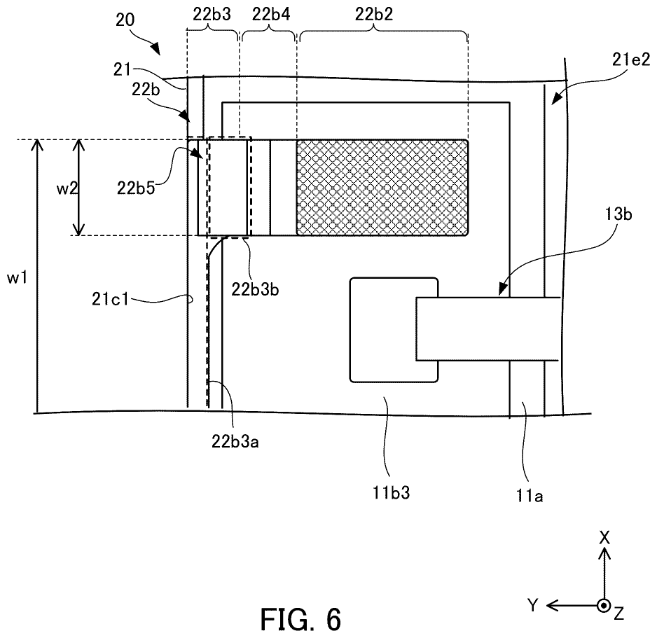

Next, the first connection terminals 22a, 22b, and 22c and the second connection terminals 23a, 23b, and 23c will be described in detail. As described above, the first connection terminals 22a, 22b, and 22c and the second connection terminals 23a, 23b, and 23c have similar configurations. The W-phase output terminal 24a, the V-phase output terminal 24b, and the U-phase output terminal 24c may also have similar configurations as the first connection terminals 22a, 22b, and 22c and the second connection terminals 23a, 23b, and 23c. Here (and in the following), the first connection terminal 22b is described as an example with reference to FIGS. 5 and 6.

FIG. 5 is a cross-sectional view of the bonding portion of the connection terminal of the semiconductor device according to the first embodiment. FIG. 6 is a plan view of the connection terminal of the semiconductor device according to the first embodiment. In FIG. 5, a portion of the first connection terminal 22b extending from the inner wall 21c1 of the frame portion 21 to the unit accommodating region 21e2 in FIG. 2 is depicted in an enlarged view. FIG. 6 represents an enlarged plan view of the first connection terminal 22b depicted in FIG. 5.

The first connection terminal 22b integrally includes a wiring portion 22b3 and a rising portion 22b4 in addition to the connecting portion 22b1 and the bonding portion 22b2. A thickness T of the first connection terminal 22b may be substantially uniform throughout. The thickness T may range from 1.0 mm to 1.4 mm, inclusive, for example, 1.2 mm.

As described above, the connecting portion 22b1 is disposed on the upper surface 21f of the frame portion 21 adjacent to the unit accommodating region 21e2 in plan view (see FIGS. 1 and 2). The bonding portion 22b2 includes a lower surface 22b8 and an upper surface 22b7 opposite the lower surface 22b8. The lower surface 22b8 (bonding surface) is bonded to the conductive circuit pattern 11b3 of the insulated circuit board 11 by ultrasonic bonding. Indentations are formed on the upper surface 22b7 opposite the lower surface 22b8. As described later, in ultrasonic bonding, a tool for ultrasonic bonding presses the upper surface 22b7 of the bonding portion 22b2 against the conductive circuit pattern 11b3 while applying ultrasonic vibration, thereby bonding the bonding portion 22b2 to the conductive circuit pattern 11b3. The pressing surface of the tool that presses the upper surface 22b7 of the bonding portion 22b2 includes a plurality of protrusions. The upper surface 22b7 of the bonding portion 22b2 is pressed by the pressing surface of the tool, so that the shape of the protrusions on the pressing surface of the tool is transferred onto the upper surface 22b7, resulting in indentations. Therefore, the indentations correspond to the locations on the upper surface 22b7 of the bonding portion 22b2 that are pressed by the tool. The indentations do not necessarily need to be formed across the entire upper surface 22b7 of the bonding portion 22b2, depending on the pressing locations of the tool on the upper surface 22b7. For example, the side of the upper surface 2267 of the bonding portion 22b2 that is adjacent to the rising portion 22b4 may have no indentations.

The wiring portion 22b3 is included in the frame portion 21, with a first end connected to the connecting portion 22b1 and partially fixed to the frame portion 21. The part of the wiring portion 22b3 that is included in the frame portion 21 is located at a height H from the front surface of the insulated circuit board 11. In a side view, the wiring portion 22b3 may have, for example, a hook shape. A second end of the wiring portion 22b3, opposite to the first end, extends in the −Y direction within the frame portion 21, and protrudes into the unit accommodating region 21e2 perpendicularly from the inner wall 21c1 of the frame portion 21.

The wiring portion 22b3 includes a first portion 22b3a and a second portion 22b3b integrally connected to the first portion 22b3a. The first portion 22b3a is included in the frame portion 21 and includes, in plan view, a first end connected to the connecting portion 22b1 within the frame portion 21 and a second end exposed from the inner wall 21c1. The width of the first portion 22b3a in the #X direction is a first width w1.

As illustrated in FIG. 6, for example, the second portion 22b3b is integrally connected in plan view to the second end of the first portion 22b3a on the +X side. The width of the second portion 22b3b in the ±X direction is a second width w2, which is smaller than the first width w1. The second width W2 may be, for example, 30% or more and 40% or less of the first width w1.

The rising portion 22b4 connects the second end of the wiring portion 22b3 (the second portion 22b3b), which is located at the extended end, to the end of the bonding portion 22b2 on the inner wall 21c1 side. The inner and outer sides of the connection between the upper end of the rising portion 22b4 and the extended end of the wiring portion 22b3 are formed as R-surfaces. A distance G from the connection (the surface of the rising portion 22b4 facing the inner wall 21c1) to the inner wall 21c1 is maintained. The shortest distance from this connection to the tip of the bonding portion 22b2 is a length L1. The distance G of the first connection terminal 22b may be approximately equal to the thickness T of the first connection terminal 22b, and may range from 1.2 mm to 4.0 mm, inclusive, for example, approximately 2.0 mm. The distance G is the same for the first connection terminals 22a and 22c and the second connection terminals 23a, 23b, and 23c.

The distance G from the inner wall 21c1 to each of the W-phase output terminal 24a, V-phase output terminal 24b, and U-phase output terminal 24c may range from 2.0 mm to 4.0 mm, inclusive, for example, approximately 4.0 mm.

The inner and outer sides of the connection between the lower end of the rising portion 22b4 and the end of the bonding portion 22b2 on the inner wall 21c1 side are also formed as R-surfaces. The shortest distance from this connection to the tip of the bonding portion 22b2 is a length L2. In plan view, the rising portion 22b4 and the bonding portion 22b2 both have the second width w2, similar to the second portion 22b3b of the wiring portion 22b3.

In the connection (corner portion) between the rising portion 22b4 and the bonding portion 22b2, a virtual intersection C is defined by a line extending in the direction through the surface of the rising portion 22b4 on the inner wall 21c1 side and a line extending in the LY direction through the lower surface 22b8 of the bonding portion 22b2, thereby defining a corner portion (virtual corner portion). The length of the rising portion 22b4 in the ±Y direction (i.e., length L1-length L2) may range from 2.8 mm to 3.2 mm, inclusive, for example, 3.0 mmm.

An extended portion of the wiring portion 22b3 of the first connection terminal 22b that extends from the inner wall 21c1 of the case 20 (the frame portion 21), which corresponds to the distance G, includes a thinned region 22b6 (a thinned portion) that is thinner than other portions of the first connection terminal 22b excluding the extended portion. Regarding the thinned region 22b6 (the thinned portion), a length g from the inner wall 21c1 to the upper end of the R-surface (i.e., the starting point of the R-surface) that connects the wiring portion 22b3 to the rising portion 22b4 is 1.2 mm or more, and, in this example, may be approximately 1.5 mm. In this example, a notch 2265 is formed on the upper surface side of the thinned region 2266 of the wiring portion 22b3.

In this example, the notch 22b5 is formed on the upper surface of the first connection terminal 22b (including the wiring portion 22b3 and the rising portion 22b4) by removing a section that extends from the connection between the rising portion 22b4 and the wiring portion 22b3 toward the inner wall 21c1, along the wiring portion 22b3, and ends just short of the inner wall 21c1. The notch 22b5 is formed so as to extend across the width of the first connection terminal 22b in the +X direction. A depth D of the notch 2265 is 15% or more and 45% or less of the thickness T of the first connection terminal 22b. Accordingly, the thickness of the thinned region 22b6 of the first connection terminal 22b is 45% more and 85% or less of the thickness T. The notch 2265 only needs to be formed at least at the connection between the wiring portion 22b3 and the rising portion 22b4. Preferably, as illustrated in FIG. 5, the notch 2265 is formed by removing not only the upper surface of the wiring portion 22b3 but also the entire upper surface of the rising portion 22b4. The notch 22b5 may be formed after the first connection terminal 22b, which does not include the notch 22b5, has been integrally formed with the completed case 20. Alternatively, the first connection terminal 22b with the notch 22b5 already formed may be integrally molded with the frame portion 21 to fabricate the case 20.

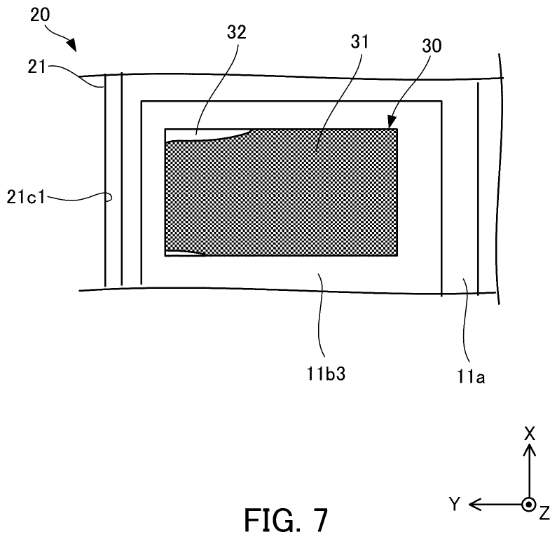

Next, bonding of the bonding portion 22b2, which is included in the first connection terminal 22b partially fixed to the frame portion 21 of the case 20, to the conductive circuit pattern 11b3 will be described with reference to FIG. 7. FIG. 7 illustrates the bonding of the connection terminal of the semiconductor device according to the first embodiment. Note that FIG. 7 schematically depicts a scanning acoustic tomography (SAT) image obtained by capturing the bonding portion 22b2 of the first connection terminal 22b, which is bonded to the conductive circuit pattern 11b3 illustrated in FIG. 6, using an ultrasonic imaging device.

A pressed region 30, in which the bonding portion 22b2 of the first connection terminal 22b is pressed against the conductive circuit pattern 11b3 by ultrasonic bonding, includes a bonded region 31 and a non-bonded region 32. The bonded region 31 is a region where the bonding portion 22b2 and the conductive circuit pattern 11b3 are bonded to each other. The non-bonded region 32 is a region where the bonding portion 22b2 and the conductive circuit pattern 11b3 are not bonded (or are not sufficiently bonded) to each other. In such a region, for example, voids may be present. According to FIG. 7, the pressed region 30 is mostly occupied by the bonded region 31, indicating that the bonding portion 22b2 is substantially reliably bonded to the conductive circuit pattern 11b3.

The bonding portions 24a2, 24b2, and 24c2, which are included in the W-phase output terminal 24a, the V-phase output terminal 24b, and the U-phase output terminal 24c, respectively, may also include a thinned region in the same manner as the first connection terminals 22a, 22b, and 22c and the second connection terminals 23a, 23b, and 23c, and may be bonded to the conductive circuit pattern 11b2.

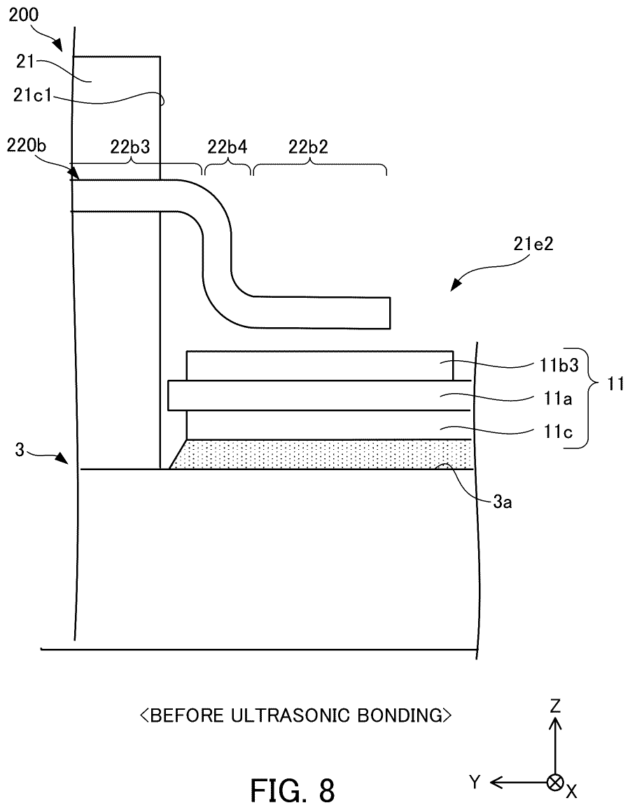

A first reference example of the semiconductor device 1 according to the first embodiment will now be described. The first reference example relates to a case where the first connection terminal 22b is not provided with the notch 22b5. The other components have the same configuration as those of the semiconductor device 1 of the first embodiment. Bonding of the first connection terminal 22b, which does not include the notch 22b5, to the conductive circuit pattern 11b3 will be described with reference to FIGS. 8 to 10. In the first reference example, components identical to those of the semiconductor device 1 of the first embodiment are designated by the same reference numerals.

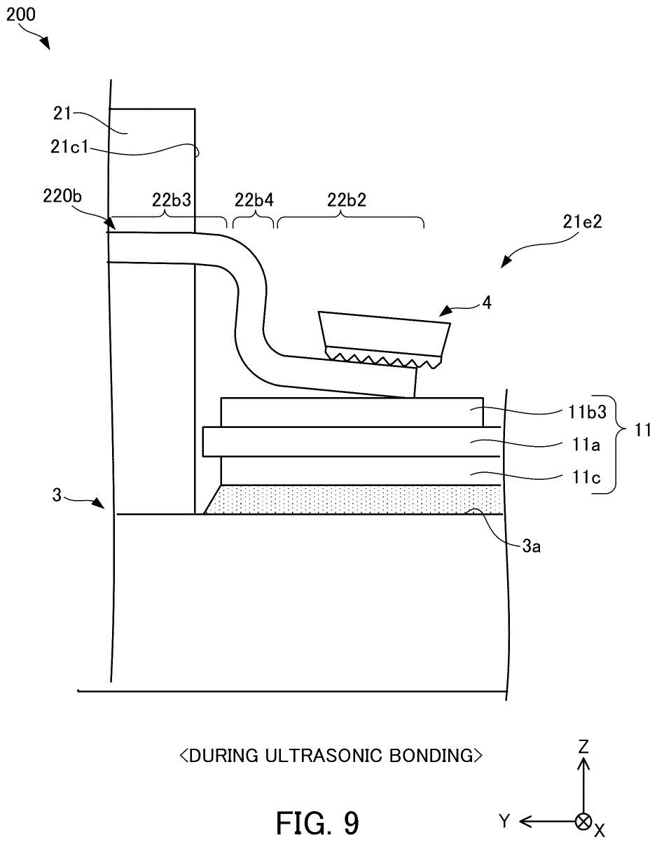

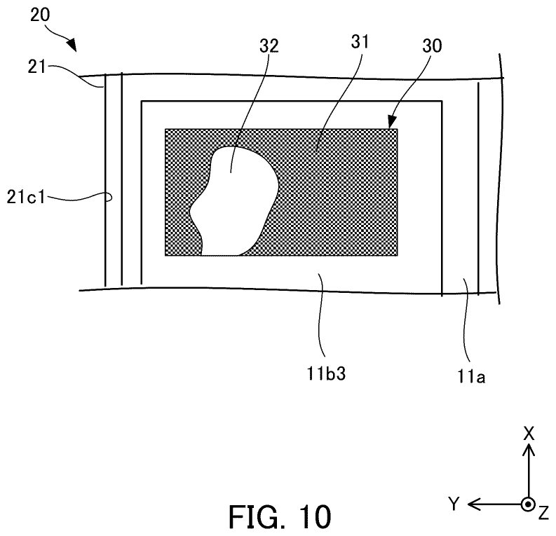

FIG. 8 is a first diagram for illustrating the bonding of the connection terminal of the semiconductor device in the first reference example. FIG. 9 is a second diagram for illustrating the bonding of the connection terminal of the semiconductor device in the first reference example. FIG. 10 illustrates the bonding of the connection terminal of the semiconductor device in the first reference example.

A case 200 of the first reference example has the same configuration as the case 20 of the first embodiment, except for a first connection terminal 220b. The first connection terminal 220b included in the case 200 of the first reference example is not provided with the notch 2265, which is formed in the first connection terminal 22b.

When manufacturing the semiconductor device using the case 200 of the first reference example, the semiconductor units 10a, 10b, and 10c, prepared in advance, are bonded to the cooling surface 3a of the cooling module 3 via the bonding members 14a.

Subsequently, the case 200 is attached to the cooling surface 3a of the cooling module 3, so that the semiconductor units 10a, 10b, and 10c are accommodated in the unit accommodating regions 21e1, 21e2, and 21e3 of the case 200, respectively. In this process, the bonding portions of the first and second connection terminals are opposed to the conductive circuit patterns 11b3 and 11b1, respectively. For example, as illustrated in FIG. 8, the bonding portion 22b2 of the first connection terminal 220b is opposed to the conductive circuit pattern 11b3 with a gap therebetween. In the following description, the first connection terminal 220b among a plurality of first and second connection terminals included in the case 200 will be described.

Next, the bonding portion 22b2 of the first connection terminal 220b is bonded to the conductive circuit pattern 11b3 by ultrasonic bonding. For example, as illustrated in FIG. 9, the bonding portion 22b2 of the first connection terminal 220b is pressed from above against the conductive circuit pattern 11b3 by a tool 4 that vibrates as part of the ultrasonic bonding apparatus.

At this time, stress is generated near the connection between the wiring portion 22b3, which is partially fixed to the frame portion 21, and the rising portion 22b4 of the first connection terminal 220b. However, as previously described, the distance G (see FIG. 5) from the inner wall 21c1 to the rising portion 22b4 is relatively short, approximately 2.0 mm. Therefore, the portion of the first connection terminal 220b corresponding to the distance G (i.e., the extended portion) has high rigidity. Even when the bonding portion 22b2 is pressed by the tool 4, the portion corresponding to the distance G of the first connection terminal 220b does not flex sufficiently. Accordingly, the entire lower surface 22b8 of the bonding portion 22b2 does not come into contact with the conductive circuit pattern 11b3. For example, as illustrated in FIG. 9, the front end side (−Y direction) of the lower surface 22b8 of the bonding portion 22b2 contacts the conductive circuit pattern 11b3, while the rear end side (+Y direction) of the lower surface 2268 of the bonding portion 22b2 has a gap with respect to the conductive circuit pattern 11b3. In this state where the lower surface 22b8 of the bonding portion 22b2 is in contact with the conductive circuit pattern 11b3 only partially, ultrasonic bonding is performed, and as a result, the bonding portion 22b2 is not sufficiently bonded to the conductive circuit pattern 11b3.

For example, according to the SAT image in FIG. 10, which illustrates the bonding portion 22b2 of the first connection terminal 220b bonded to the conductive circuit pattern 11b3 in the first reference example, the area of the non-bonded region 32 included in the pressed region 30 is larger than that in the case of the first embodiment. Thus, the bonding portion 22b2 of the first connection terminal 220b is not sufficiently bonded to the conductive circuit pattern 11b3.

A second reference example will now be described. In the first reference example, the distance G from the inner wall 21c1 to the rising portion 22b4 in the first connection terminal 220b is relatively short. Therefore, the portion of the first connection terminal 220b corresponding to the distance G has high rigidity, and the bonding portion 22b2 of the first connection terminal 220b is not reliably bonded to the conductive circuit pattern 11b3.

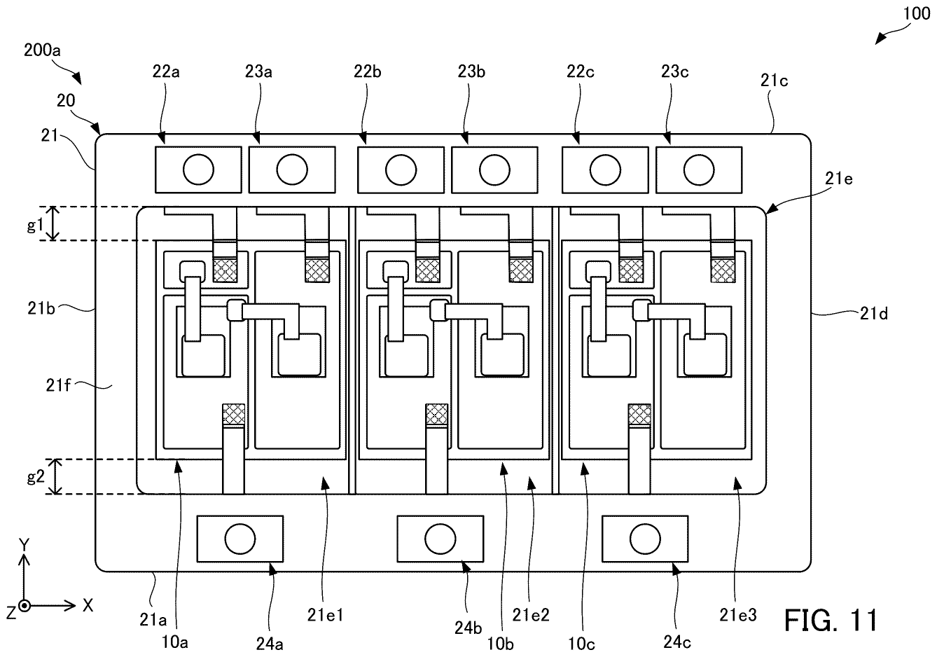

On the other hand, in the second reference example, it is conceivable to reduce the rigidity of the portion corresponding to the distance G of the first connection terminal 220b by increasing the distance G. This case will be described with reference to FIG. 11. FIG. 11 is a plan view of the semiconductor device of the second reference example.

In a semiconductor device 100 depicted in FIG. 11, the first and second connection terminals used in the semiconductor device 1 of the first embodiment are the ones from the first reference example (i.e., those without the respective notches formed), and the distance G is further increased. Therefore, the first and second connection terminals are reliably bonded to the insulated circuit substrate 11 by ultrasonic bonding.

However, in the semiconductor device 100, increasing the distance G results in increased distances g1 and g2 compared to the semiconductor device 1 of the first embodiment. That is, the semiconductor device 100 has a larger footprint than the semiconductor device 1, which makes it difficult to achieve miniaturization.

The above-described semiconductor device 1 includes: the conductive circuit pattern 11b3 included in the insulated circuit substrate 11; the case 20 having a frame shape in plan view and including the inner unit accommodating region 21e2 that accommodates the conductive circuit pattern 11b3; and the first connection terminal 22b including the wiring portion 22b3 that is partially fixed to the case 20 and extends into the unit accommodating region 21e2, and the bonding portion 22b2 that has the lower surface 22b8 bonded to the conductive circuit pattern 11b3 and has indentations on its upper surface 2267 opposite to its lower surface 22b8. The wiring portion 22b3 of the first connection terminal 22b includes an extended portion that extends from the inner wall 21c1 of the case 20 and includes a thinned region 22b6 that is thinner than the other portions of the first connection terminal 22b excluding the extended portion. In this semiconductor device 1, because the extended portion of the first connection terminal 22b extending from the inner wall 21c1 of the case 20 includes the thinned region 22b6, its rigidity is reduced. Accordingly, there is no need to increase the length of the extended portion of the first connection terminal 22b, so that miniaturization of the semiconductor device 1 is not hindered, and the bondability of the bonding portion 22b2 of the first connection terminal 22b to the conductive circuit pattern 11b3 is improved.

In the first embodiment, the notch 22b5 formed in the first connection terminal 22b has a rectangular shape in a side view. However, the shape of the notch 22b5 is not limited to a rectangle, provided that formation of the thinned region 22b6 is ensured. Various examples of the notch 22b5 are described below.

### Modification 1-1

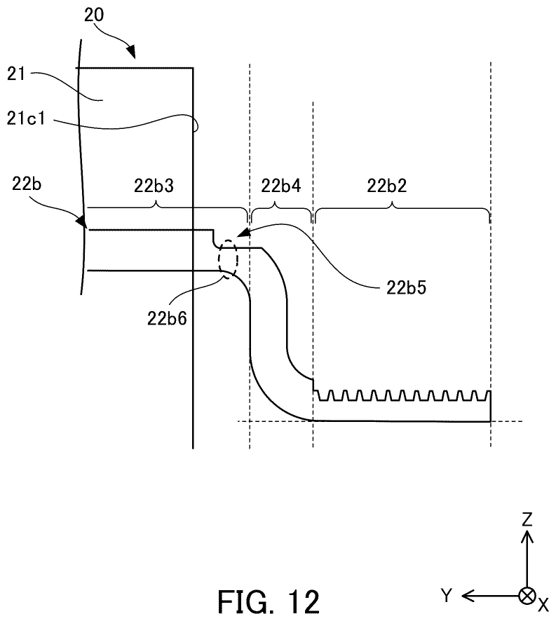

The first connection terminal 22b in a modification 1-1 will be described with reference to FIG. 12. FIG. 12 is a cross-sectional view of the bonding portion of the connection terminal in the semiconductor device according to the first embodiment (the modification 1-1). FIG. 12 corresponds to FIG. 5 of the first embodiment, and the illustration of the insulated circuit substrate 11 is omitted.

The notch 2265 formed on the upper surfaces of the wiring portion 22b3 and the rising portion 22b4 of the first connection terminal 22b illustrated in FIG. 12 has a corner that is R-chamfered in a side view. Even in this case, the rigidity of the wiring portion 22b3 and the rising portion 22b4 of the first connection terminal 22b is designed to be reduced, as in the first embodiment. In addition, the R-chamfered corner of the notch 2265 reduces stress concentration at the corner when the first connection terminal 22b is bent. As a result, the occurrence and propagation of cracks at the corner is reduced, which in turn suppresses degradation of the long-term reliability of the first connection terminal 22b.

### Modification 1-2

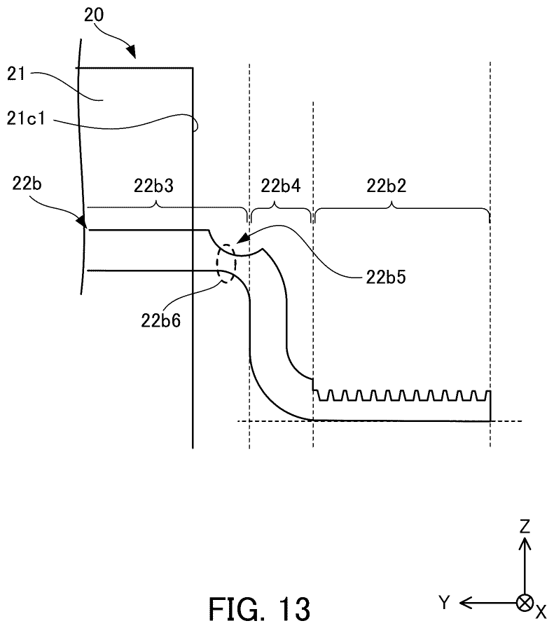

The first connection terminal 22b in a modification 1-2 will be described with reference to FIG. 13. FIG. 13 is a cross-sectional view of the bonding portion of the connection terminal in the semiconductor device according to the first embodiment (the modification 1-2). FIG. 13 corresponds to FIG. 5 of the first embodiment, and the illustration of the insulated circuit substrate 11 is omitted.

The notch 2265 formed on the upper surfaces of the wiring portion 22b3 and the rising portion 22b4 of the first connection terminal 22b depicted in FIG. 13 has an arc shape in a side view. Even in this case, the rigidity of the wiring portion 22b3 and the rising portion 22b4 of the first connection terminal 22b is designed to be reduced, as in the first embodiment. Furthermore, since the arc-shaped notch 22b5 does not include corners, stress concentration is reduced when the first connection terminal 22b is bent, as in the modification 1-1. As a result, the occurrence and propagation of cracks at the notch 22b5 is reduced, which in turn suppresses degradation of the long-term reliability of the first connection terminal 22b.

### (b) Second Embodiment

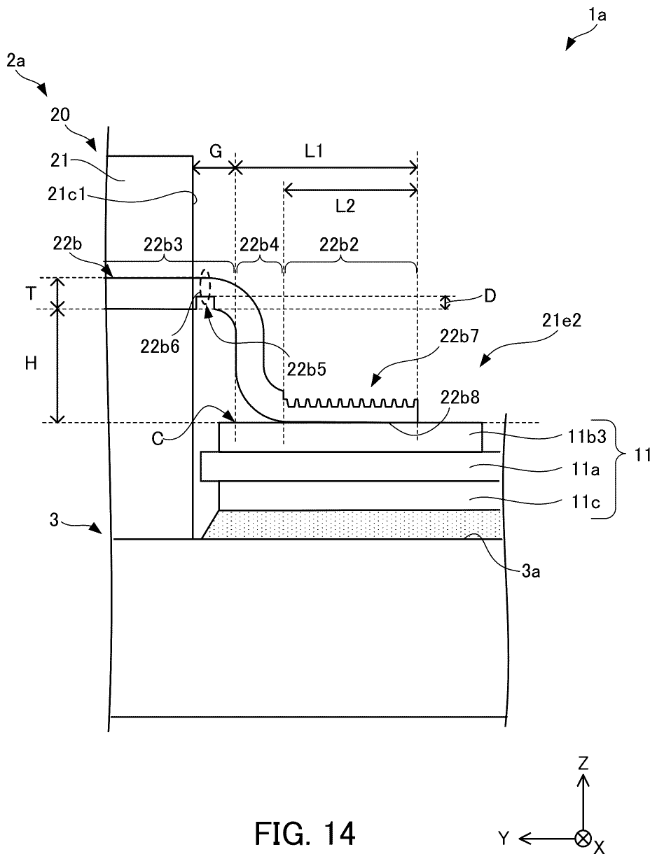

A semiconductor device according to a second embodiment will be described with reference to FIG. 14. FIG. 14 is a cross-sectional view of the bonding portion of the connection terminal in the semiconductor device according to the second embodiment. Note that FIG. 14 corresponds to FIG. 5 of the first embodiment.

Also in a semiconductor device 1a of the second embodiment, the thinned region 22b6 is provided in the first connection terminal 22b. However, in the second embodiment, the notch 22b5 is formed on the lower surface of the wiring portion 22b3 of the first connection terminal 22b. Except for the notch 22b5, the semiconductor device 1a has the same configuration as the semiconductor device 1.

The notch 22b5 is formed on the lower surface of the wiring portion 22b3 of the first connection terminal 22b, between the connection where the rising portion 22b4 is joined to the wiring portion 22b3 and a position along the wiring portion 22b3 just short of the inner wall 21c1. Here, the notch 2265 is formed in a part of the wiring portion 22b3 that is parallel to the cooling surface 3a of the cooling module 3. The notch 22b5 extends across the width of the first connection terminal 22b in the #X direction.

Both in a side view and in plan view, the notch 22b5 has a rectangular shape. The volume of the notch 22b5 may be such that the strength of the first connection terminal 22b is maintained at or above a certain level. For example, the depth D of the notch 22b5 may be 15% or more and 45% or less of the thickness T of the first connection terminal 22b. Accordingly, the thickness of the thinned region 22b6 of the first connection terminal 22b becomes 45% or more and 85% or less of the thickness T. The length of the notch 22b5 in the ±Y direction may be, for example, 5% or more and 15% or less of the length of the extended portion of the wiring portion 22b3 that extends from the inner wall 21c1.

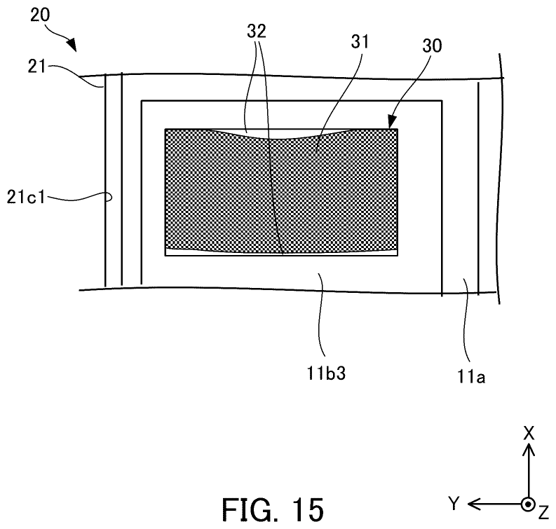

As in the first embodiment, the bonding portion 22b2 of the first connection terminal 22b is bonded to the conductive circuit pattern 11b3 by ultrasonic bonding. An SAT image of the bonding portion 22b2 bonded in this manner will be described with reference to FIG. 15. FIG. 15 illustrates bonding of the connection terminal of the semiconductor device according to the second embodiment. Similar to FIG. 7, FIG. 15 schematically depicts an SAT image of the bonding portion 22b2 of the first connection terminal 22b, which is bonded to the conductive circuit pattern 11b3 in FIG. 14, as captured by an ultrasonic imaging device.

According to the SAT image, depicted in FIG. 15, of the bonding portion 22b2 of the first connection terminal 22b, which is bonded to the conductive circuit pattern 11b3 in the semiconductor device of the second embodiment, the non-bonded region 32 within the pressed region 30 is observed to be significantly smaller than the bonded region 31. It is also evident that the bonded region 31 has a larger area than in the case of the first embodiment. This indicates that the bonding portion 22b2 of the first connection terminal 22b is almost reliably bonded to the conductive circuit pattern 11b3.

Therefore, even when the notch 22b5 is formed on the lower surface of the wiring portion 22b3 of the first connection terminal 22b, the rigidity of the first connection terminal 22b is reduced, as in the first embodiment. Accordingly, there is no need to increase the length o f the extended portion of the first connection terminal 22b, so that miniaturization of the semiconductor device 1 is not hindered, and the bondability of the bonding portion 22b2 of the first connection terminal 22b to the conductive circuit pattern 11b3 is improved.

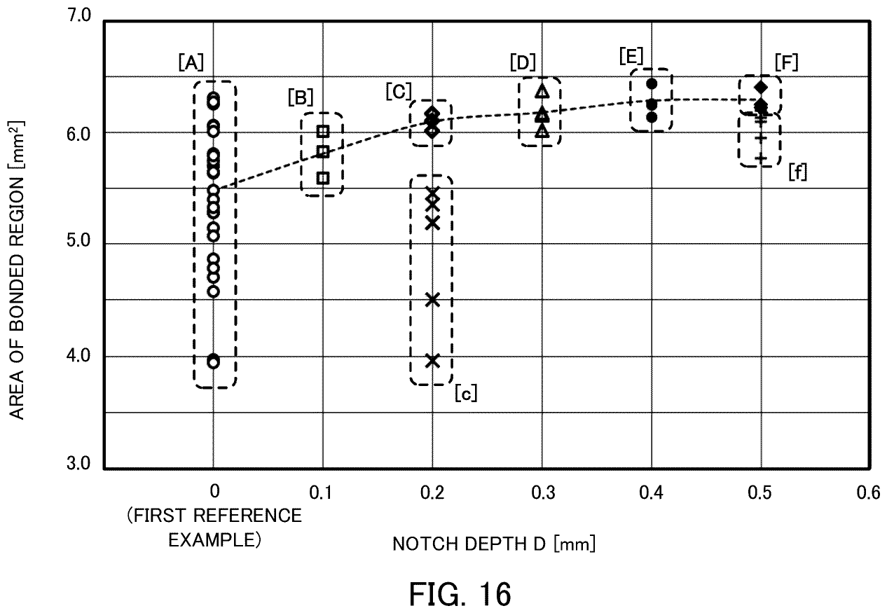

Next, with reference to FIG. 16, a description will be given of changes in the bonded region 31 of the bonding portion 22b2 to the conductive circuit pattern 11b3 in accordance with the notch depth of the notch 22b5 in the second embodiment.

FIG. 16 is a graph illustrating the area of the bonded region in relation to the notch depth of the connection terminal in the second embodiment. In FIG. 16, the horizontal axis represents the notch depth D [mm], and the vertical axis represents the area of the bonded region [mm²] corresponding to the notch depth.

FIG. 16 illustrates the area of the bonded region 31, as described with reference to FIG. 15, for the bonding portions 22b2 of eight types of the first connection terminals 22b that are ultrasonically bonded to the conductive circuit pattern 11b3. In each case, multiple samples of each type are ultrasonically bonded to the conductive circuit pattern 11b3. The number of samples varies depending on the type.

The eight types include, first, the case where the notch 22b5 is not formed (○ in FIG. 16). This corresponds to the first reference example, and in FIG. 16, it is represented as a case where the notch depth D is 0 mm. This result is indicated as [A] in FIG. 16.

Next is the case where the notch 22b5 is formed on the lower surface of the wiring portion 22b3 of the first connection terminal 22b. This corresponds to the second embodiment. Five types in this case are presented for notch depths D of 0.1 mm (□ in FIGS. 16) , 0.2 mm (⋄), 0.3 mm (Δ), 0.4 mm (●), and 0.5 mm (♦). These results are indicated as [B], [C], [D], [E], and [F] in FIG. 16.

Further, there is a case where the notch 22b5 is formed on the upper surface of the wiring portion 22b3 of the first connection terminal 22b. This corresponds to the first embodiment. Two types are presented for notch depths D of 0.2 mm (× in FIGS. 16) and 0.5 mm (+). These results are indicated as [c] and [f] in FIG. 16.

First, comparing [A] (the first reference example) with the second embodiment ([B], [C], [D], [E], and [F]), it is seen that the variation in the area of the bonded region 31 is smaller in the second embodiment, and the nonuniformity is suppressed. That is, when the notch 22b5 is formed on the lower surface of the wiring portion 22b3 of the first connection terminal 22b, more stable bonding is achieved.

Moreover, in the second embodiment, as the notch depth D increases (in the order of [B], [C], [D], [E], and [F], where each subsequent depth is greater than the previous one), the area of the bonded region 31 increases, at least up to a notch depth of 0.5 mm, relative to a thickness of 1.2 mm of the wiring portion 22b3 of the first connection terminal 22b.

Furthermore, comparing the second embodiment ([C] and [F]) with the first embodiment ([c] and [f] ), although in both cases the area of the bonded region 31 increases as the notch depth D increases, the second embodiment achieves more stable and reliable bonding.

Additionally, in the first embodiment, the variation in the bonded region 31 is smaller when the notch depth D is 0.5 mm than when it is 0.2 mm. In this range, it is considered that the bonding becomes more stable as the notch depth D increases in the first embodiment.

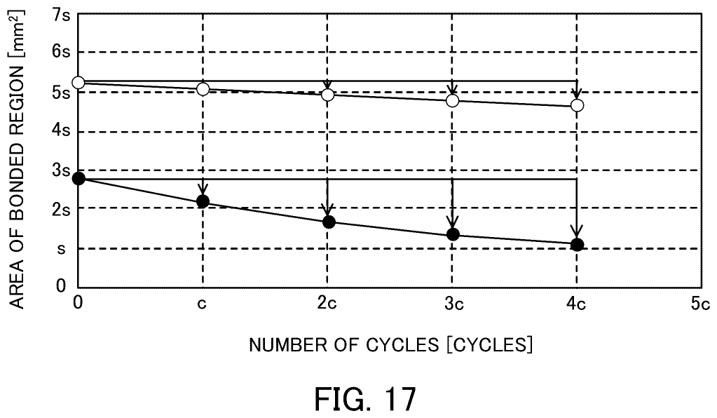

Next, with reference to FIG. 17, a description will be given of changes in the area of the bonded region of the bonding portion 22b2 to the conductive circuit pattern 11b3 in accordance with the number of cycles in a thermal cycling test in the second embodiment. FIG. 17 is a graph illustrating the area of the bonded region of the connection terminal in the semiconductor device according to the second embodiment, in relation to the number of thermal cycles.

In FIG. 17, the horizontal axis represents the number of cycles of the thermal cycling test performed on the first connection terminal 22b. The scale on the horizontal axis uses “c” as a reference cycle count, with increments labeled as 2c, 3c, and so on. The vertical axis represents the area [mm²] of the bonded region 31 corresponding to each number of cycles. The scale on the vertical axis uses “s” as a reference value for the area of the bonded region, with increments labeled as 2s, 3s, and so on.

In FIG. 17, the white circles (○) represent the case of the first connection terminal 22b in the second embodiment, and the black circles (⋅) represent the case where the notch 22b5 is not formed in the first connection terminal 22b, which corresponds to the first reference example.

According to the graph in FIG. 17, in the case where the notch 2265 is not formed (black circles), the area of the bonded region of the bonding portion 22b2 of the first connection terminal 22b decreases as the number of cycles in the thermal cycling test increases. This indicates that, as the number of thermal cycles increases, delamination of the bonding portion 22b2 of the first connection terminal 22b progresses. In addition, as the number of thermal cycles increases (to 2c, 3c, and so on), the rate of decrease in the area of the bonded region also increases.

On the other hand, in the case of the first connection terminal 22b of the second embodiment (white circles), even before the thermal cycling test is conducted (i.e., at 0 cycles), the area of the bonded region of the bonding portion 22b2 increases by approximately 1.67 times compared to the case without the notch 22b5 (black circles).

In the case of the first connection terminal 22b of the second embodiment (white circles), the area of the bonded region of the bonding portion 22b2 also decreases as the number of cycles in the thermal cycling test increases. However, compared to the case without the notch 22b5 (black circles), the rate of decrease is reduced, meaning that the decrease occurs more gradually.

From the above, it is understood that, by forming the notch 22b5 on the lower surface of the wiring portion 22b3 of the first connection terminal 22b in the second embodiment, the bonding portion 22b2 of the first connection terminal 22b is reliably bonded to the conductive circuit pattern 11b3.

Furthermore, in the second embodiment as well, as in the first embodiment, the notch 22b5 formed in the first connection terminal 22b is not limited to a rectangular shape, as long as the notch 22b5 is capable of defining the thinned region 22b6. Various examples of the notch 22b5 will be described below.

### Modification 2-1

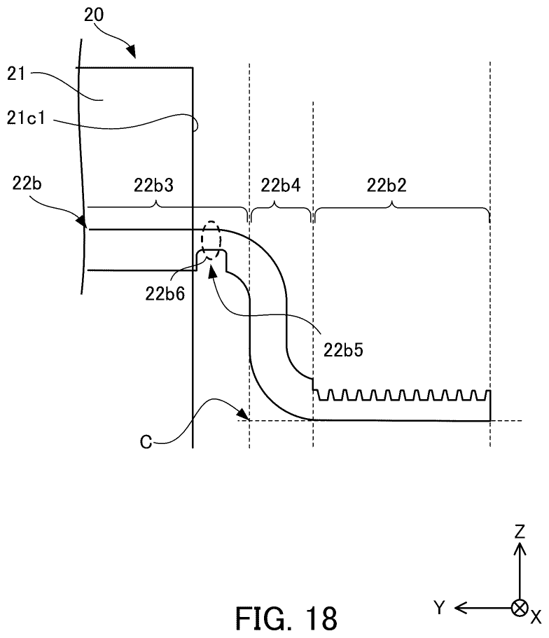

The first connection terminal 22b of a modification 2-1 will be described with reference to FIG. 18. FIG. 18 is a cross-sectional view of the bonding portion of the connection terminal in the semiconductor device according to the second embodiment (the modification 2-1). Note that FIG. 18 corresponds to FIG. 14 of the second embodiment, and the illustration of the insulated circuit board 11 is omitted.

In the first connection terminal 22b depicted in FIG. 18, the notch 22b5 formed in the wiring portion 22b3 has rounded corners (R-chamfered) in a side view. Even in this case, as in the second embodiment, it is possible to reduce the rigidity of the wiring portion 22b3 and the rising portion 22b4 of the first connection terminal 22b. Furthermore, by R-chamfering the corners of the notch 22b5, concentration of stress that would otherwise occur at the corners when the first connection terminal 22b bends is reduced. As a result, both the occurrence of cracks at the corners and the propagation of such cracks are reduced.

### Modification 2-2

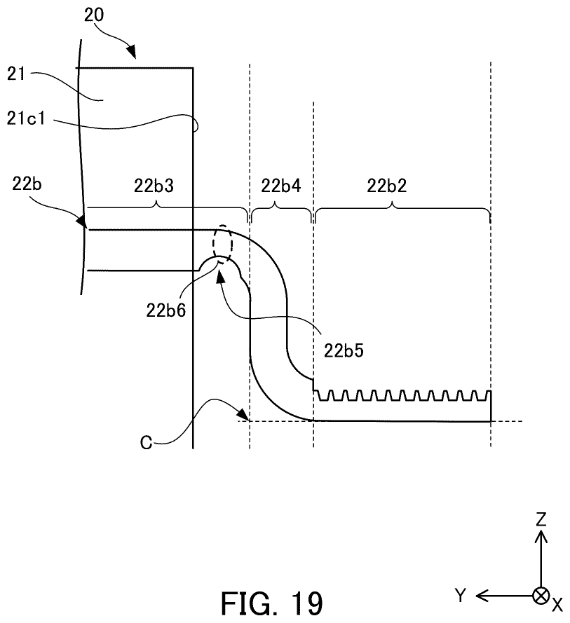

The first connection terminal 22b of a modification 2-2 will be described with reference to FIG. 19. FIG. 19 is a cross-sectional view of the bonding portion of the connection terminal in the semiconductor device according to the second embodiment (the modification 2-2). FIG. 19 corresponds to FIG. 14 of the second embodiment, and the illustration of the insulated circuit board 11 is omitted.

The notch 2265 formed on the lower surface of the wiring portion 22b3 of the first connection terminal 22b illustrated in FIG. 19 is arcuate in a side view. Even in this case, as in the second embodiment, the rigidity in the extended portion of the wiring portion 2263 of the first connection terminal 22b is reduced. Furthermore, since the notch 22b5 has an arcuate shape and therefore includes no corners, the concentration of stress when the first connection terminal 22b is bent is reduced, as in the modification 2-1. Accordingly, both the occurrence of cracks at the notch 22b5 and the propagation of such cracks are reduced.

### Modification 2-3

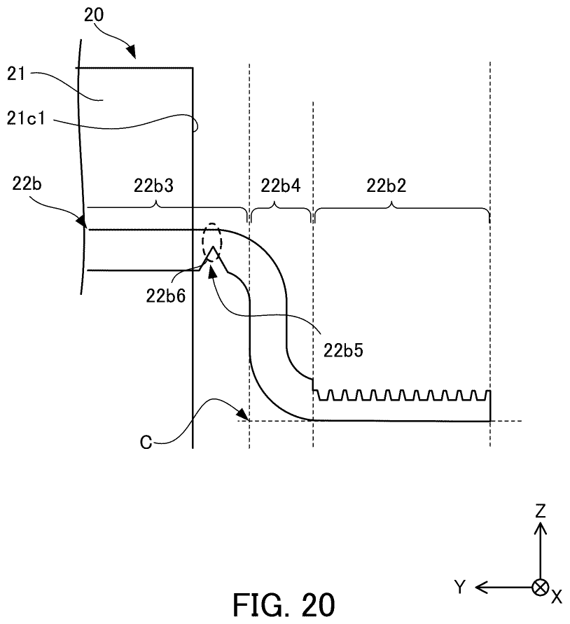

The first connection terminal 22b of a modification 2-3 will be described with reference to FIG. 20. FIG. 20 is a cross-sectional view of the bonding portion of the connection terminal in the semiconductor device according to the second embodiment (the modification 2-3). FIG. 20 corresponds to FIG. 14 of the second embodiment, and the illustration of the insulated circuit board 11 is omitted.

The notch 22b5 formed on the lower surface of the wiring portion 22b3 of the first connection terminal 22b illustrated in FIG. 20 is triangular in a side view. Even in this case, as in the second embodiment, the rigidity in the extended portion of the wiring portion 22b3 of the first connection terminal 22b is reduced.

### (c) Third Embodiment

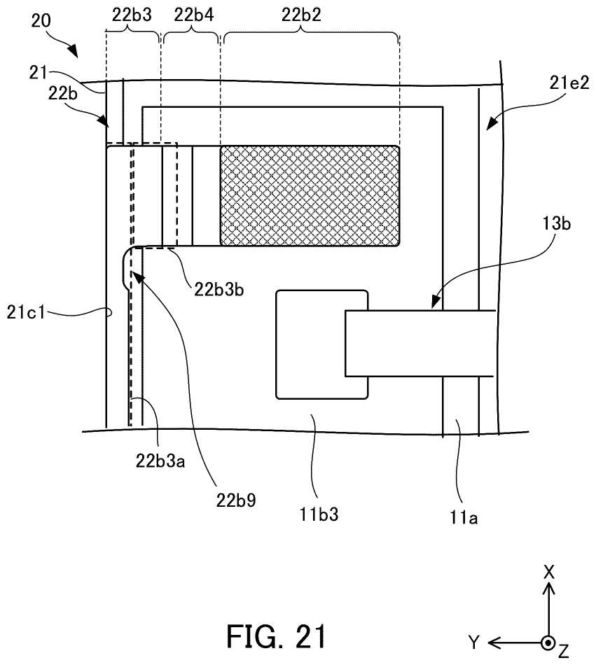

In the third embodiment, in the wiring portion 22b3 of the first connection terminal 22b of the first and second embodiments, a side of the first portion, adjacent to the location where the second portion is connected, is recessed. This case will be described with reference to FIG. 21.

FIG. 21 is a plan view illustrating the connection terminal of the semiconductor device according to the third embodiment. FIG. 21 corresponds to FIG. 6, and the components denoted by the same reference numerals as in FIG. 6 are the same as those depicted in FIG. 6. In the first connection terminal 22b illustrated in FIG. 21, a recess 22b9 is formed in a side of the first portion 22b3a of the wiring portion 22b3, adjacent to the location where the second portion 22b3b is connected. The recess 2269 is formed in the first portion 22b3a so as to include a corner portion defined by the first portion 22b3a and the second portion 22b3b. Both corners at the back end of the recess 22b9 may be R-shaped surfaces.

First, a case in which the recess 22b9 is not provided in the first connection terminal 22b will be described. The first connection terminal 22b is obtained by performing blanking on a flat conductive plate by pressing, and then performing bending on the blanked conductive plate.

The first connection terminal 22b thus obtained without the recess 22b9 is prone to stress concentration in the vicinity of the corner portion formed by the first portion 22b3a and the second portion 22b3b (in the vicinity of the base of the second portion 22b3b). When the bonding portion 22b2 of the first connection terminal 22b is ultrasonically bonded to the conductive circuit pattern 11b3, stress tends to concentrate at the base, leading to a higher possibility of crack initiation and propagation.

Therefore, in the third embodiment, the recess 22b9 is formed in the first portion 22b3a adjacent to the base of the second portion 22b3b of the first connection terminal 22b. This reduces the stress concentration in this portion. Accordingly, a reduction in the service life of the first connection terminal 22b is suppressed, and a reduction in reliability is mitigated.

In the wiring portion 22b3 of the first connection terminal 22b of the first and second embodiments, the second portion 22b3b is connected to the X-direction end of the first portion 22b3a in plan view. Therefore, the recess 22b9 is formed on one side of the base of the second portion 22b3b. When the second portion 22b3b is connected, for example, to the center of the first portion 22b3a in plan view, the recess 22b9 may be formed on both sides of the base of the second portion 22b3b.

The recess 22b9 may also be applied to the first embodiment, modifications 1-1 and 1-2, the second embodiment, and modifications 2-1, 2-2, and 2-3. In any of these cases, as in the third embodiment, the stress concentration at the base of the second portion 22b3b is reduced.

According to the disclosed techniques, the bondability of terminals to conductive plates is improved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a conductive plate;
a case having a frame shape in a plan view of the semiconductor device, to thereby form an inner accommodating region in which the conductive plate is housed; and
a terminal, including:
a wiring portion that is partially fixed to the case and extends into the inner accommodating region, and
a bonding portion, including:
a bonding surface bonded to the conductive plate, and
a main surface opposite to the bonding surface, and having indentations formed thereon, wherein
the wiring portion includes an extended portion extending from the case, the extended portion including a thinned portion that is thinner than all other portions of the terminal excluding the extended portion.

2. The semiconductor device according to claim 1, wherein:
the case includes an inner wall that defines the inner accommodating region,
the wiring portion of the terminal extends from the inner wall of the case into the inner accommodating region, and
the extended portion of the wiring portion extends from the inner wall Of the case into the inner accommodating region.

3. The semiconductor device according to claim 2, wherein:
the thinned portion of the terminal has a notch formed on an upper surface or a lower surface thereof.

4. The semiconductor device according to claim 3, wherein:
the wiring portion extends into the inner accommodating region in an extending direction, and the notch is formed across the thinned portion in a width direction orthogonal to the extending direction.

5. The semiconductor device according to claim 2, wherein:
the wiring portion is located above the bonding portion, and has an extending end extending into the inner accommodating region in an extending direction,
the bonding portion has a first end and a second end opposite to each other in the extending direction, the first end being closer to the inner wall,
the terminal further includes a rising portion connecting the first end of the bonding portion and the extending end of the wiring portion, and
a shortest distance in the extending direction from the inner wall to the rising portion is 1.2 mm or more and 4.0 mm or less.

6. The semiconductor device according to claim 2, wherein:
the wiring portion extends into the inner accommodating region in an extending direction, and the wiring portion includes:
a first portion that has a first width in a width direction orthogonal to the extending direction in the plan view, and
a second portion that is integrally connected to the first portion and has a second width, which is smaller than the first width, in the width direction.

7. The semiconductor device according to claim 6, wherein:
the second portion of the wiring portion has a base, and
the first portion of the wiring portion has a recess that is formed at a location corresponding to at least one side of the base of the second portion, and is recessed towards the inner wall.
